(19) United States
(12) Patent Application Publication
(10) Pub. No.: US 2006/0132873 A1
(43) Pub. Date: Jun. 22, 2006

(54) Image processing apparatus

(75) Inventor: Mieko Ohkawa, Tokyo (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: Konica Minolta Business Technologies, Inc., Tokyo (JP)

(21) Appl. No.: 11/232,755

(22) Filed: Sep. 22, 2005

(30) Foreign Application Priority Data
Dec. 20, 2004 (JP) JP2004-367706

(51) Int. Cl. G03F 3/08

(52) U.S. Cl. 358/518

(57) ABSTRACT

An image processing apparatus, provided with: a member which designate a color; and a color adjusting unit which adjusts a color by increasing a first hue data value of a first area in a similar color range to a designated color and decreasing a second hue data value of a second area in the similar color range.

This application is based on Japanese Patent Application No. 2004-367706 filed on Dec. 20, 2004 in Japanese Patent Office, the entire content of which is hereby incorporated by reference.

### BACKGROUND OF THE INVENTION

The present invention relates to an image processing apparatus that conducts color adjustment of an image, an image processing system, an image forming system and a program thereof.

In general, when an image is outputted to a color printer or a color copying machine, color adjustment is sometimes conducted for specific colors.

For example, there is suggested an image processing apparatus wherein specifying a color signal subject to adjustment in RGB calorimetric system as an adjusting point, and specifying an amount of adjustment for the adjusting point on Lab colorimetric system, based on this amount of adjustment, an adjusting function for color signals in surrounding area including adjusting point is calculated (see Patent literature 1).

Patent literature 1: Unexamined Japanese Patent Application Publication No. 2004-72272.

In the prior art stated above, it was not considered that the tone of whole color in surrounding area including the color designated by a user is changed, although colors in surrounding area including adjusting point was changed in accordance with an amount of adjustment.

The invention has been achieved in view of aforesaid problems in the prior art, and an object of the invention is to provide an image processing apparatus, an image processing system, an image forming system and a computer program to enable various color expressions of the color included in the color area near the specified color.

### SUMMARY OF THE INVENTION

An embodiment to solve the problems is an image processing apparatus having: a member which designate a color; and a color adjusting unit which adjusts a color by increasing a first hue data value of a first area in a similar color range to a designated color and decreasing a second hue data value of a second area in the similar color range.

### BRIEF DESCRIPTION OF THE DRAWINGS

FIG. 1 is a block diagram indicating functional structure of an image forming apparatus 10 in an embodiment;

FIG. 2(a) is an example of a conversion curve in the case of making hue data value of similar color range close to hue data value h₀ of a designated color;

FIG. 2(b) is an example of a conversion curve in the case of making hue data value of similar color range away from a hue data value h₀ of a designated color;

FIG. 3 is a flow chart showing color adjustment process executed in the image forming apparatus 10;

FIG. 4 shows an example of an operation screen displayed on operation display 12 when a color and an amount of color adjustment are designated;

FIG. 5 shows an example of conversion curves wherein a degree of moving a hue data value of similar color range close to a hue data value of a designated color is gradually changed;

FIG. 6 shows another example of conversion curves wherein a degree of moving a hue data value of similar color range close to a hue data value of a designated color is gradually changed;

FIG. 7 is another example of an operation screen where a color and an amount of color adjustment are designated;

FIG. 8 is a diagram explaining a setting method of similar color ranges in the case where 3 points are picked out as designated colors;

FIG. 9(a) is a graph showing amount of change Δh₁ calculated by Gaussian function;

FIG. 9(b) is a graph showing amount of change Δh₂ calculated by Gaussian function;

FIG. 9(c) is a graph showing amount of change Δh in similar color range;

FIG. 10 is a conversion curve of a relation ship between input hue data hᵢₙ and output hue data hₒᵤₜ;

FIG. 11 is an other example of a forming method of conversion curve; and

FIG. 12 is a drawing showing an example wherein comparing the inclination of the segment connecting peaks of reverse S-shape curve with a predetermined value, an amount of color adjustment is modified in accordance with the result of the comparison i.e. if the inclination is larger than the predetermined value or smaller.

FIG. 13 is an example of the conversion curve.

### DETAILED DESCRIPTION OF THE PREFERRED EMBODIMENT

In the following columns, image forming apparatus 10 of the present embodiment of the invention is explained.

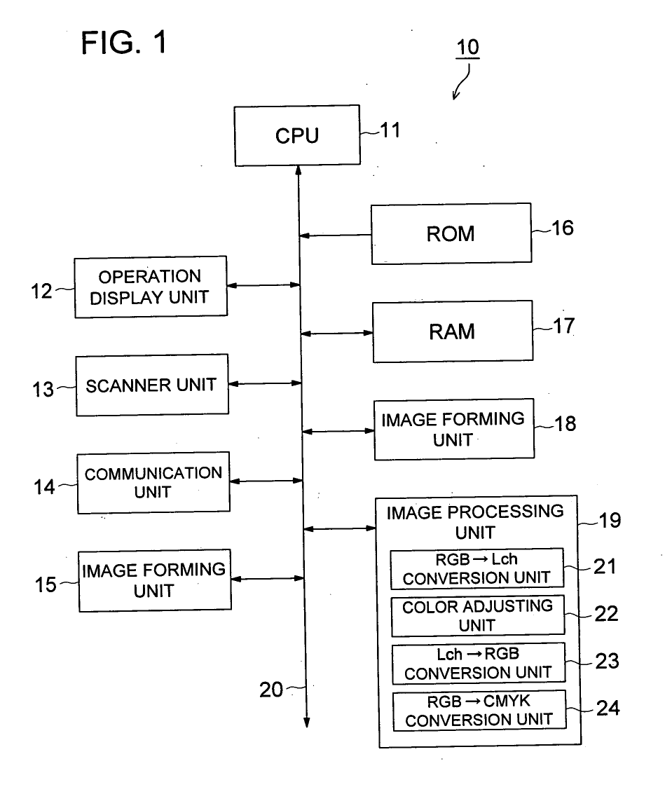

A functional structure of the image forming apparatus 10 is shown in FIG. 1. As FIG. 1 shows, the image forming apparatus 10 has a CPU (Central Processing Unit) 11, operation display 12, scanner unit 13, communication unit 14, image forming unit 15, ROM (Read Only Memory) 16, RAM (Random Access Memory) 17, memory unit 18, and image processing unit 19 and each unit is connected by bus line 20.

In accordance with data inputted from the communication unit 14 or various instructions inputted through the operation display 12, the CPU 11 expands a designated program among the programs stored in the ROM 16, over work area in the RAM 17, conducts several tasks collaborating with aforesaid program and stores a result of conduction in the RAM 17.

Operation display 12 is constructed with LCD (Liquid Crystal Display) and displays various operation buttons, statuses of each unit, and actions of each function following instructions of display signals inputted through the CPU 11. Also, on the LCD display screen, a pressure sensitive (pressure sensitive resister film) touch panel having thereon the transparent electrodes arranged in a grid form, in which X-Y coordinates of the pressure-point are detected by fingers or a touch pen as a voltage value and detected position signal is outputted to the CPU 11 as an operation signal.

Scanner unit 13 is composed of a light source, a lens, and a CCD (Charge Coupled Section). Scanner unit 13 reads an image on a document to obtain image data by forming a focused images of reflected light with irradiating and scanning documents with the light form the light source, and by conducting photo-electric conversion.

Communication unit 14 is an interface to send and receive various kinds of information such as image data, to and from the outside.

Image forming unit 15 forms images by an electrophotographic method based on image data (CMYK data). Specifically, the image forming unit 15 has an exposure unit, a developing unit and a fixing unit. A photosensitive drum is exposed to light by the exposing unit, and an electrostatic latent image is formed on the photosensitive drum base on image data, and then toner is adhered on the photosensitive drum based on the electrostatic latent image, in the developing unit. Then the toner adhered on the photosensitive drum is transferred onto printing paper and is fixed on printing paper by heat by the fixing unit.

ROM 16 constructed by nonvolatile semiconductor memory stores programs and data to be executed by the CPU 11.

RAM 17 is constructed by re-writable semiconductor element and it is a storage medium storing data temporally, in which a program area to spread programs conducted by the CPU 11 and a data area to store various results of execution by the CPU 11, are formed.

The memory 18 constructed to be provided with a HDD (Hard Disk Drive) and stores various pieces of information such as image data obtained by the scanner unit 13, image data received by communication unit 14 and image data processed by the image processing unit 19.

Image processing unit 19 includes RGB→Lch conversion unit 21, color adjusting unit 22, Lch→RBG conversion unit 23 and RGB→CMYK conversion unit 24. The image processing unit 19 realizes software process with the collaboration of the image processing programs stored in the ROM 16 and the CPU 11.

The RGB→Lch conversion unit 21 converts image data obtained by the scanner unit 13 or received by the communication unit 14 from RGB data into Lch data, according to the conversion formulas (1)-(7) below.

First, using optimized masking coefficient (3×3 matrix), RGB data is converted into XYZ data in accordance with conversion formula (1).

$$\begin{matrix}( Numeral Expression 1 ) & \\ ( \begin{matrix}X \\ Y \\ Z\end{matrix} ) = ( \begin{matrix}0.336 & 0.396 & 0.037 \\ 0.048 & 0.871 & - 0.059 \\ - 0.043 & 0.03 & 0.921\end{matrix} ) * ( \begin{matrix}R \\ G \\ B\end{matrix} ) & ( 1 )\end{matrix}$$

In the next, in accordance with the conversion formulas (2)-(4), XYZ data calculated by conversion formula (1) are converted into Lab data (referring to P127 “Color Engineering” by Noboru Ohta, issued by Tokyo Electronics University Publication Station), provided that tristimulus colorimetry values of neutral point at a light source D65 are (Xw, Yw, Zw)=(0.9504, 1.0, 1.0889).

$$\begin{matrix}( Numeral Expression 2 ) & \\ L = 116 * {( \frac{Y}{Yw} )}^{\frac{1}{3}} - 16 & ( 2 ) \\ a = 500 * \{ {( \frac{X}{Xw} )}^{\frac{1}{3}} - {( \frac{Y}{Yw} )}^{\frac{1}{3}} \} & ( 3 ) \\ b = 200 * \{ {( \frac{Y}{Yw} )}^{\frac{1}{3}} - {( \frac{Z}{Zw} )}^{\frac{1}{3}} \} & ( 4 )\end{matrix}$$

Next, Lab data calculated by the conversion formulas (2)-(4) are converted into Lch data in accordance with the conversion formulas (5)-(7).

$$\begin{matrix}( Numeral Expression 3 ) & \\ L = L & ( 5 ) \\ c = \sqrt{{a}^{2} + {b}^{2}} & ( 6 ) \\ h = arc tan \frac{b}{a} & ( 7 )\end{matrix}$$

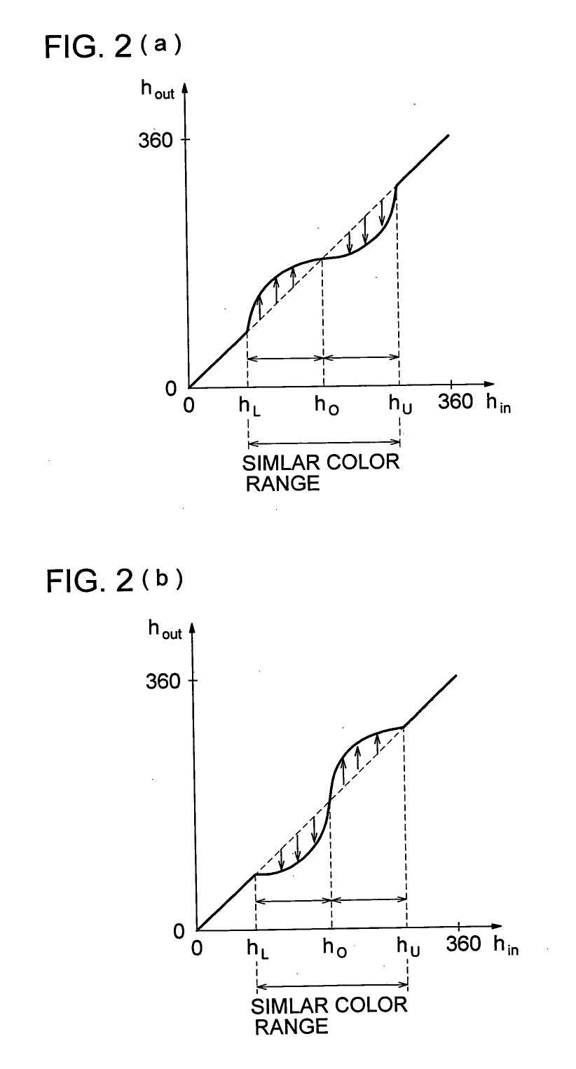

The color adjusting unit 22 adjusts colors by increasing hue data of the first area in the similar color range of a designated color and by decreasing hue data of the second area in the similar color range of a designated color. While the details are mentioned afterwards, this color adjustment can be realized by the reverse S-Shape curve (refer to FIG. 2(a)) or S-shape curve (refer to FIG. 2(b)) in a conversion curve. The similar color rage means the area to be subjected to color adjustment including a designated color. Further, the color adjusting unit 22 maintains and does not change a hue data value of the designated color. In addition, the color adjusting unit 22 checks whether an output hue data value increases or decreases monotonously including no-change in response to an input hue data value. If it is neither monotonous increase nor monotonous decrease, the output hue data value is modified.

Each of FIG. 2(a) and FIG. 2(b) is example of a curve showing an input hue data value hᵢ versus an output hue data value hₒᵤₜ used when color adjustment is done by the color adjusting unit 22.

As FIG. 2(a) shows, in case of increasing a hue data value from a lower limit value h_{L} in the similar color range to a hue data value hₒ of a designated color and decreasing a hue data value from a hue data value h₀ of a designated color to an upper limit value hᵤ in the similar color range, a hue data value in the similar color range comes close to the hue data value hₒ of the designated color. In this case, for the data within a predetermined area near the designated color in similar color range, the amount of change is made larger as the data goes away from the designated color and for the data outside the predetermined area, the amount of change is made smaller as the data goes away from the designated color, and the data outside the similar color rage is made to remain the same. Thereby, when a hue data value in the similar color range comes close to a hue data value hₒ of a designated color, the conversion curve forms a reverse S-shaped curve.

On the other hand, as FIG. 2(b) shows, in case of increasing a hue data value from hue data value hₒ of a designated color to an upper limit value hᵤ in the similar color range and decreasing a hue data value from lower limit value h₁ in the similar color range to hue data value h₀ of a designated color, the hue data value in the similar color range goes away from the hue data value hₒ of the designated color. Herein, for the data inside a predetermined area near the designated color in the similar color range, the amount of change is made larger as the data goes away from the designated color and for the data outside the predetermined area, the amount of change is made smaller as the data goes away from the designated color, the data outside the similar color rage is made to remain the same. Thereby, when a hue data value in the similar color range comes close to a hue data value hₒ of designated color, the conversion curve forms a S-shape curve.

Incidentally, as an example of the conversion curve showing an input hue data value hᵢₙ versus an output hue data value hₒᵤₜ, a color adjustment shown in FIG. 13 is considered. In this example, based on adjusting amount Δhₜ for a hue data hₜ to be adjusted, adjusting is done also for the hue data included in a surrounding area of adjusting point hₜ, hence the color tone of an image is changed. However, in this method there is a problem that the color tone of total image is changed.

The Lch→RGB conversion unit 23 converts Lch data including h data-after color adjustment into RGB data in accordance with the conversion formulas (8)-(14) below.

First, Lch data is converted into Lab data in accordance with the conversion formulas (8)-(10).

(Numeral Expression 4)
L=L (8)
a=c*cos h (9)
b=c*sin h (10)

Next, Lab data calculated by conversion formula (8) (10) are converted into XYZ data in accordance with the conversion formulas (11) (13) (Light source D65).

$$\begin{matrix}( Numeral Expression 5 ) & \\ X = {( \frac{a}{500} + \frac{L + 16}{116} )}^{3} * Xw & ( 11 ) \\ Y = {( \frac{L + 16}{116} )}^{3} * Yw & ( 12 ) \\ Z = {( - \frac{b}{200} + \frac{L + 16}{116} )}^{3} * Zw & ( 13 )\end{matrix}$$

Next, XYZ data calculated by the conversion formulas (11)-(13) are converted into RGB data in accordance with the conversion formula (14).

$$\begin{matrix}( Numerical Expression 6 ) & \\ ( \begin{matrix}R \\ G \\ B\end{matrix} ) = ( \begin{matrix}3.151 & - 1.423 & - 0.219 \\ - 0.165 & 1.219 & 0.085 \\ 0.153 & - 0.106 & 1.073\end{matrix} ) * ( \begin{matrix}X \\ Y \\ Z\end{matrix} ) & ( 14 )\end{matrix}$$

The RGB→CMYK conversion unit 24 converts RGB data after color adjustment into CMYK data.

Next, actions of the image forming apparatus 10 are explained.

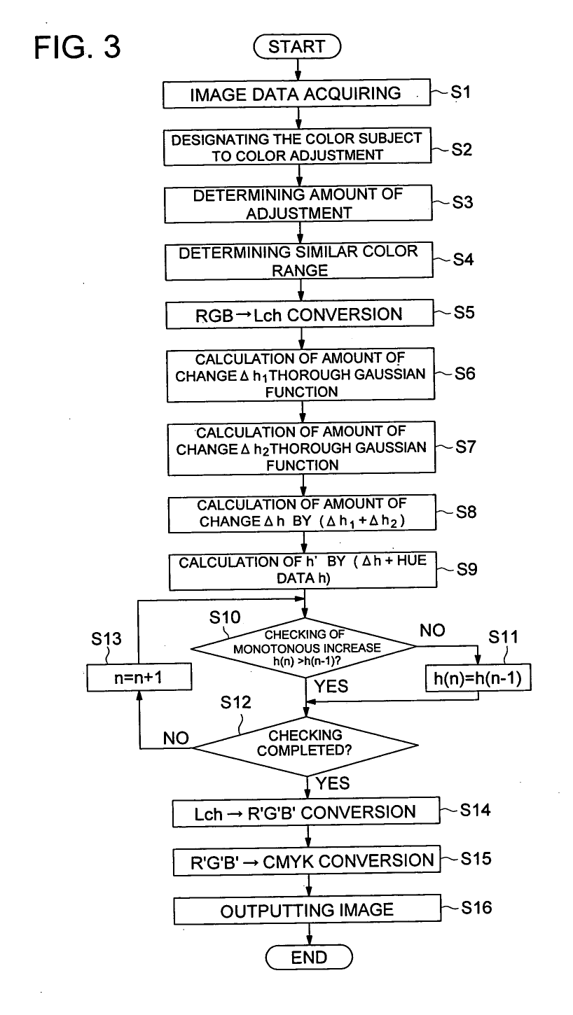

FIG. 3 is a flow chart showing color adjustment processing conducted in the image forming apparatus 10. First of all, the scanner unit 13 reads a document to obtain an image data. (Step S1)

Next, with instructions by a user, one or more colors to be subjected to color adjustment are designated through the operation unit 12 (Step S2). Also, with instructions from a user, an amount of color adjustment to be conducted by color adjusting unit 22 is designated in gradation from the operation display unit 12 (Step S3).

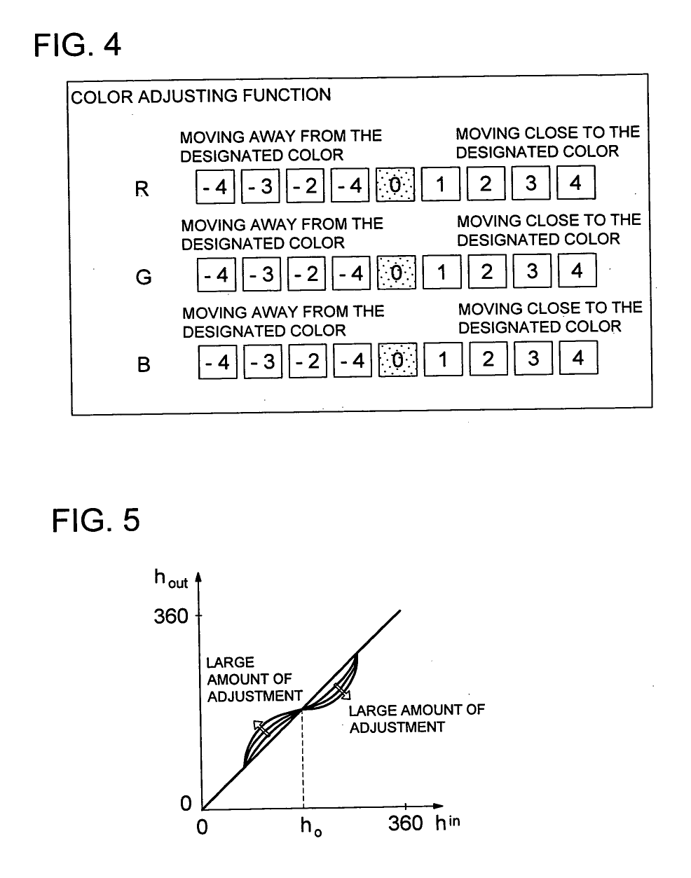

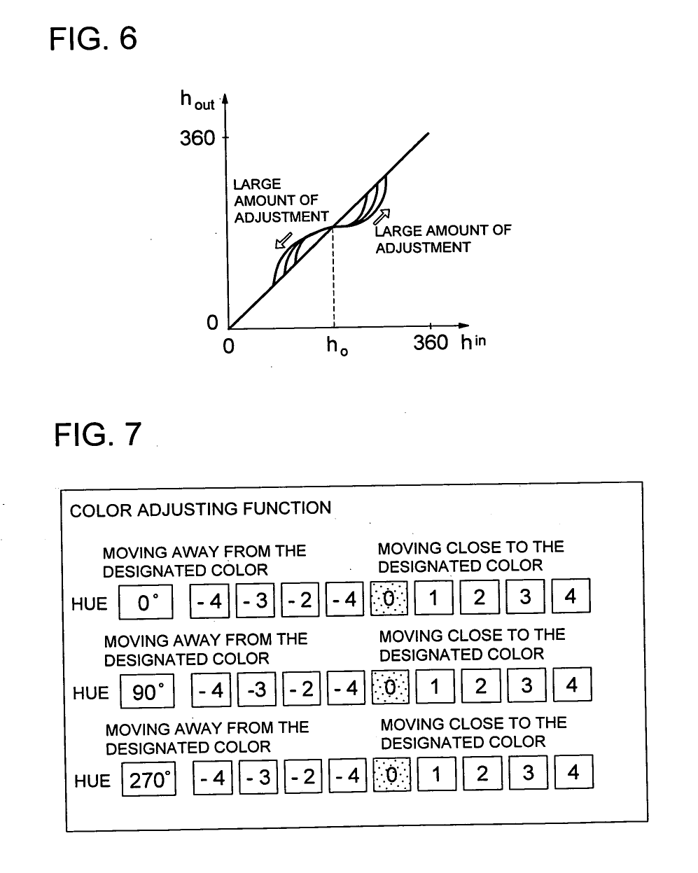

FIG. 4 shows an example of an operation screen displayed on the operation display 12 when a color and an amount of color adjustment are designated. As FIG. 4 shows, the color can be designated in R,G and B. Also, by designating each of R, G and B colors, the degree of coming close to or going away from the designated color can be selected among “−4” to “4”. In this case, the direction coming close to the hue data value of designated color is defined as plus. FIG. 5 shows an example of a conversion curve wherein the degree of making a hue data value in a similar color range close to a hue data value of a designated color is gradually changed. By adjusting a bulge of the curve gradually, the degree of coming close to the designated color is adjusted. Also, as FIG. 6 shows, by changing the breadth of the similar color range, the degree of coming close to the designated color may also be adjusted.

Meanwhile, as FIG. 7 shows, by designating color with inputted hue angle, the degree of coming close to or going away from the designated color can be set for each hue angle. Also the color can be designated by “a” data value and “b” data value in Lab data.

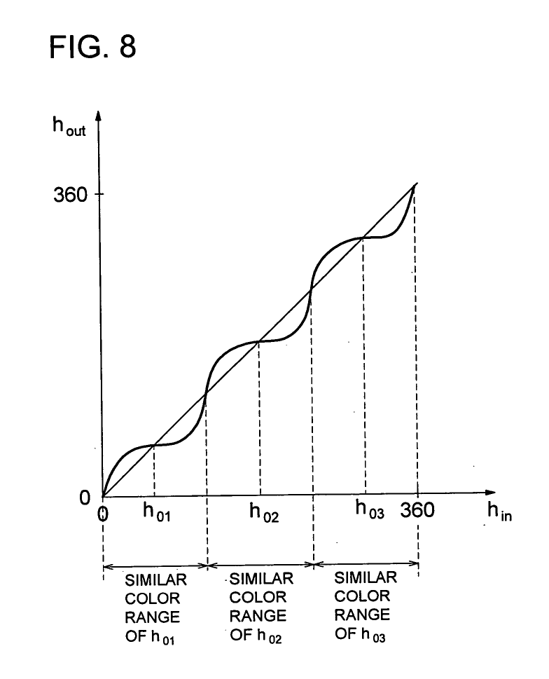

Next, the similar color range correspond to each designated color is established (Step S4). In case the designated colors are two or more, the similar color rages are determined so that each similar color range of different designated color does not overlap each other. The breadth of each similar color range includes each designated color and is not less than 0 degree and not more than the value obtained by dividing 360 degrees by the number of the designated colors. FIG. 8 shows an example of conversion curve where 3 points are taken as the designated colors. Corresponding to the designated colors h₀₁, h₀₂ and h₀₃, each similar color rage is determined so that each similar color rage does not overlap each other.

The method of determining the similar color ranges for two designated colors is explained. Assuming that hue data values of designated colors are represented by “a” and “b”, the breadth of the similar color ranges for “a” and “b” are not less than 0°, and not more than 360°/2=180°. In case the breadth of the similar color range for “a” and “b” is 180 degree, for instance, the area of the similar color range for a can be made to be from:
a−{(360−b)+a}/2 to a+(b−a)/2
and the area of the similar color rage for b can be made to be from:
b−(b−a)/2 to b+{(360−b)+a}/2.

Herein, if calculated value c is not less than 360 degrees. A range of 0 to (c-360) degree is to be included in the area. Also if calculated value c is less than 0°, a range of (360+c) degrees to 360 degrees is to be included in the area.

Specifically, supposing that a=60 degrees, and b=10 degrees, the area of the similar color rage for a is −75 degrees (285 degrees) to 105 degrees and the area of the similar color range for b is 105 degrees to 285 degrees.

Next, through the RGB→Lch conversion unit 21, an image data obtained by the scanner unit 13 is converted from RGB data into Lch data (Step 5) in accordance with conversion formulas (1)-(7).

Next, with Gaussian function, amount of change Δh₁ in an area where a hue data value is increased in the similar color rage of a designated color is calculated (Step 6). The Gaussian function is the function (15) indicated by the formula (15) below.

$$\begin{matrix}( Numeral Expression 7 ) & \\ g = u * exp [ - π \{ {( \frac{L - {L}_{center}}{{L}_{limit}} )}^{2} + {( \frac{c - {c}_{center}}{{c}_{limit}} )}^{2} + {( \frac{h - {h}_{center}}{{h}_{limit}} )}^{2} \} ] & ( 15 )\end{matrix}$$

Herein, each of L_{center}, c_{center} and h_{center} is the center of data which is to be changed. Each of Lₗᵢₘᵢₜ, cₗᵢₘᵢₜ and hₗᵢₘᵢₜ is a range of data which are to be changed, and “u” indicates an amount of adjustment.

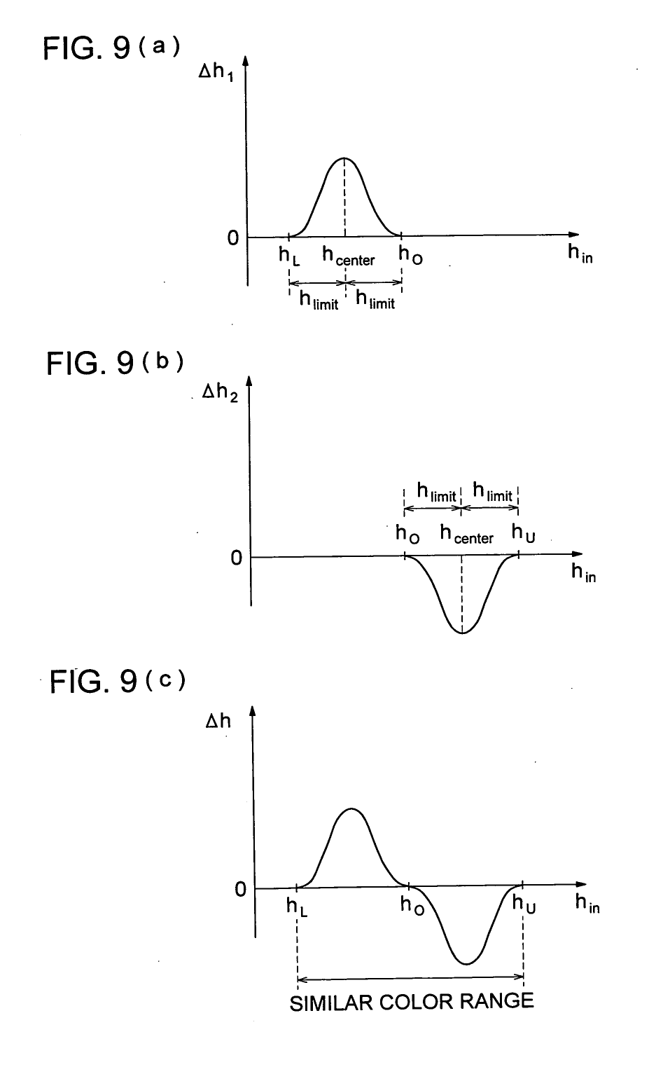

In FIG. 9(a), amount of change Δh₁ corresponding to input hue data value hᵢₙ is shown. The amount of change Δh₁ is calculated by the formula (15) in which h center is located at a position which halves a distance from a lower limit h_{L} in the similar color range of a designated color to a hue data value hₒ of a designated color into two equal parts, a distance from h center to the hue data h₀ is represented by hₗᵢₘᵢₜ and adjusting value is represented by +u. Herein, an occasion where a hue data value in the similar color area moves close to a hue data value h₀ of designated color, i.e. an occasion where conversion curve is reverse S-shape, is explained. Meanwhile, adequate values are used for L_{center} and c_{center}, and the values capable of covering whole brightness solid and chroma solid are used for Lₗᵢₘᵢₜ and cₗᵢₘᵢₜ.

In the same manner, an amount of change Δh₂ in the area where a hue data value is decreased in the similar color range of a designated color is calculated through Gaussian function (Step S7). FIG. 9(b) shows amount of change Δh₂ corresponding to an input hue data value hᵢₙ. The amount of change Δh₂ is calculated by the formula (15) in which h_{center} is located in the position which halves a distance from upper limit value hᵤ in the similar color range of a designated color to a hue data value h₀ of a designated color into two equal parts, a distance from h_{center} to the hue data value h₀ is represented by hₗᵢₘᵢₜ and adjusting value is represented by −u.

Next, amount of change Δh₁ and amount of change Δh₂, are added and amount of change Δh in the similar color range is calculated (Step S8). FIG. 9(c) shows amount of change Δh in similar-color range corresponding to input hue data value hᵢₙ.

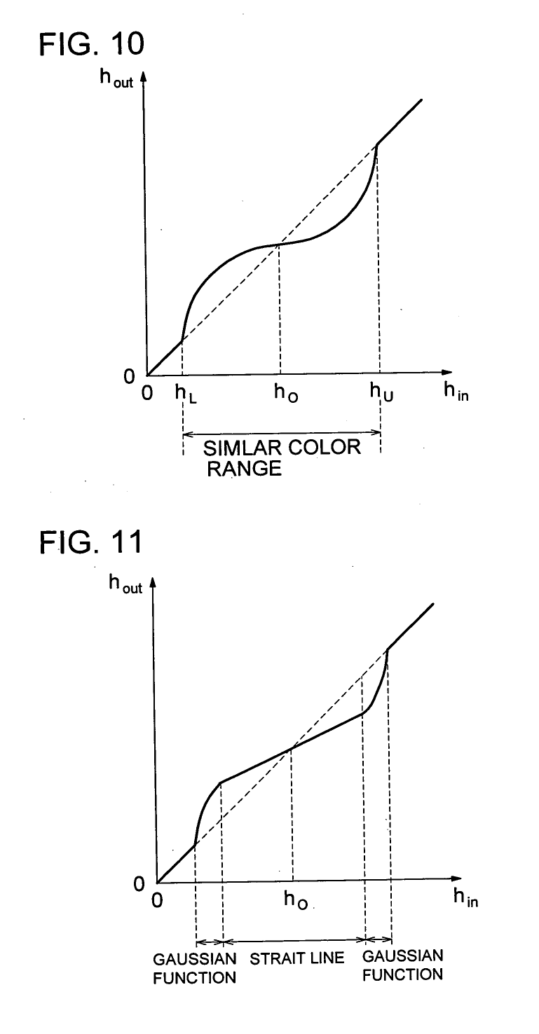

Then, the hue data h and the amount of change Δh are added to calculate hue data h′ after color adjustment (Step S9). In FIG. 10, output hue data value hₒᵤₜ (an hue data h′ after color adjustment) corresponding to input hue data value hᵢₙ is shown.

Herein, the output data hue hₒᵤₜ is checked if it increases monotonously including no-change corresponding to the input hue data hᵢₙ (Step S10). Supposing that a hue data value is h(n) at hue angle n degree, (herein n=1,2, . . . , 360), satisfaction of h (n)≦h (n−1) is judged, whether it is satisfied or not. If h (n)≦h (n−1) is not satisfied (Step S10; NO), output hue data value hₒᵤₜ is modified, (Step S11), by making h(n) equivalent to h(n−1).

In Step S10, if h (n)≦h (n−1) is satisfied (Step S10; YES) or if output hue data value hₒᵤₜ is modified since h (n)≦h (n−1) is not satisfied (Step S11), the completion of checking for all the hue data values is judged. (Step S12)

In case the checking is not completed, (Step S12; NO), n is incremented (Step S13) and the process returns to Step S10.

If the checking is completed (Step S12; YES), Lch data including h′ after color adjustment is converted into R′G′B′ data through Lch→RGB converting unit 23 in accordance with conversion formulas (8)-(14) (Step S14). Then R′G′B′ data after color adjustment are converted into CMYK data through RGB→CMYK conversion unit 24 (Step S15).

Next, through the image forming unit 15, an image is formed based on CMYK data and is output (Step S16).

In the above, color adjustment executed in the image forming unit 10 is completed.

In the image forming apparatus 10 of the present embodiment, a hue data value of a first area in the similar color range of a designated color is increased and a hue data value of a second area in the similar color range of a designated color is decreased thus, various expressions of color included in color area near the designated color can be realized. Also the hue data value of the designated color is maintained thus, various expressions of the colors included in a color area near the designated color can be realized without changing the designated color. Practically, when the color adjustment indicated in FIG. 2(a) is made, the color expressed by those close to the designated color are increased, since the hue data value of similar color area of the designated color can be moved close to the hue data value h₀ of the designated color. On the other hand, when color adjustment indicated in FIG. 2(b) is done, the colors expressed by those close to the designated color is decreased, since the hue data value of similar color area of the designated color is moved away from the hue data value h₀ of the designated color.

Also, incase two or more colors are designated, it is possible to prevent that adjustment of other designated color is affected by the color adjustment of each designated color, since the similar color range of each designated color is assigned so that similar color range of different designated colors do not overlap each other.

Also, since the output hue data is corrected so that out put hue data value increases monotonously or decreases including no-change corresponding to input hue data value, inversion of hue is prevented.

Meanwhile, aforesaid description in the present embodiment shows examples of an image processing unit, an image processing system, an image forming system and a program related to the invention, and the information is not limited to this embodiment. The details of image forming unit 10 in the aforesaid embodiment may be modified appropriately in the scope that does not depart from the spirit of the invention.

For instance, it is also possible to obtain the conversion curve by using the value calculated by Gaussian function for the area outside the similar color are and by connecting with straight line the peaks of the curve expressed by Gaussian function for the area inside the similar color range as FIG. 11 shows through the amount of change of the hue data value is calculated by Gaussian function in aforesaid embodiment. It is further possible to make a S-shaped curve or a reverse S-shape curve by using a spline curve which passes through the designated color and the points of both ends of the similar color range. Further, by storing table data indicating S-shaped and/or reverse S- shaped curve in memory unit 18 beforehand, an output hue data corresponding to an input hue data may be calculated.

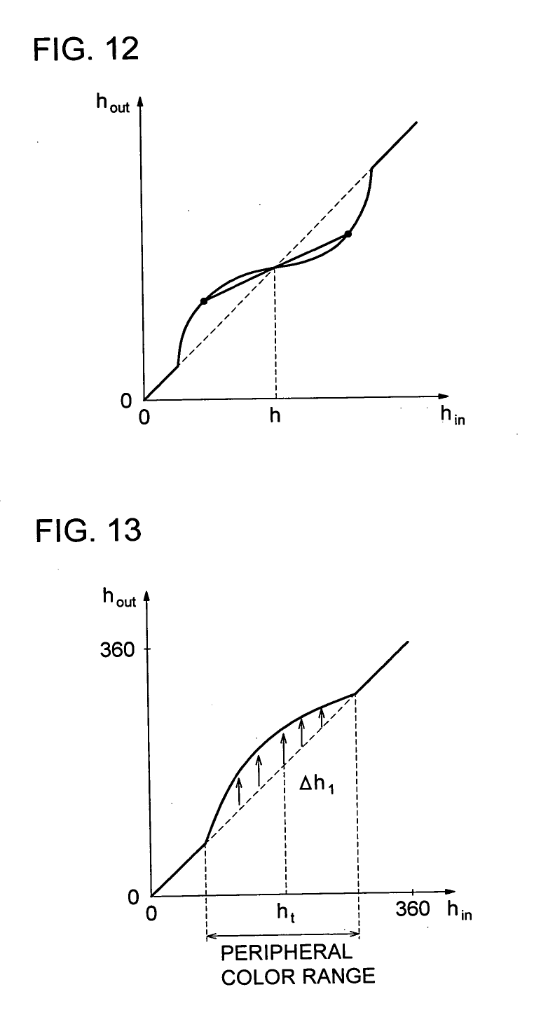

Further, in aforesaid embodiment, by comparing each hue data value in succession to check if it is monotonous increase or not, the output hue data value is corrected in case it is not monotonous increase. However, as FIG. 12 shows, by comparing the inclination of a segment connecting peaks of S-shaped curve or reverse S-shaped curve with a predetermined value, the amount of color adjustment may be altered depending on the result of the comparison.

Furthermore, in aforesaid embodiment, though the image forming apparatus 10 is provided with the operation display unit 12, the scanner unit 13, the image forming unit 15 and the image processing unit 19, one or more of these units can be provided as separate units and can be connected directly or through network. Even in the image processing system or image forming system with the functions of image forming apparatus 10, the invention can realize also.

As another example of the image processing apparatus, the invention is also applicable to an image processing apparatus which is realized by a PC (Personal Computer) and an image processing software.

Also in the above embodiment, there has been explained an example wherein the image data obtained by the scanner unit 13, was made to be a target of color adjustment, color adjustment may be applied also for the image data received by a communication unit 14 or image data obtained by an unillustrated memory medium reading means.

It is understood from the description above that various merits can be achieved through the following items of embodiments.

(1) An image processing apparatus having a color adjusting unit which adjusts color by increasing a hue data value of a first area in the similar color range of the designated color and by decreasing a hue data value in a second area in aforesaid similar color range.

(2) The image processing apparatus according to the item (1), wherein aforesaid color adjusting unit maintains a hue data value of said designated color.

(3) The image processing apparatus according to the item (1) or the item (2), wherein there is provided an operation section, which specifies an amount of color adjustment to be conducted by aforesaid color adjusting unit.

(4) The image processing apparatus according to the item (1), (2) or (3), wherein an operation section to designates one or more designated colors, is provided.

(5) The image processing apparatus according to the item (1), (2), (3) or (4), wherein the color adjusting unit establishes the similar color range of each designated color so that similar color ranges of different designated colors do not overlap each other when the number of designated colors is two or more.

(6) The color processing section according to the item (1), (2), (3), (4) or (5), wherein the color adjusting unit checks if the output hue data value for input hue data value is monotonous increase or monotonous decrease including no-change, and correct aforesaid output hue data value in case the output hue data value is neither monotonous increase nor monotonous decrease.

(7) The image processing apparatus according to the item (1), (2), (3), (4), (5) or (6), wherein the image obtaining section, which obtains image data, is provided and the aforesaid color adjusting unit: adjusts the hue data value of image data obtained by the aforesaid data obtaining section.

(8) The image processing apparatus according to any one of the Items (1), (2), (3), (4), (5), (6), and (7), wherein a first conversion unit, which converts RGB data into Lch data, is provided and aforesaid hue data value is h data value obtained by the first conversion unit.

(9) The image processing apparatus according to item (8), further provided with a second conversion unit which converts Lch data including h data after color adjustment into RGB data.

(10) The image processing apparatus according to item (9), wherein a third conversion unit, which converts RGB data obtained through aforesaid second converting section into CMYK data, and an image forming unit, which forms an image based on aforesaid CMYK data, are provided.

(11) An image processing apparatus comprising a color adjusting unit which moves a hue in the similar color area of a designated color close to the hue of aforesaid designated color.

(12) An image processing apparatus comprising a color adjusting unit, which moves a hue in the similar color area of designated color away from the hue of aforesaid designated color.

(13) The image processing system comprising a color adjusting unit which increases a hue data value of a first area in the similar color range of a designated color and decreases a hue data value of a second area in the similar color range to conduct color adjustment.

(14) The image processing system according to item (13), wherein aforesaid color adjusting unit maintains a hue data value of aforesaid designated color.

(15) The image processing system according to item (13) or (14), comprising an operation section which determines an amount of color adjustment to be conducted by aforesaid color adjusting unit.

(16). The image processing system according to item (13), (14) or (15), comprising an operating section to designate one or more colors mentioned above.

(17) The image processing system according to item (13), (14), (15) or (16), wherein when the number of designated colors is two or more, aforesaid color adjusting unit determines the similar color ranges of different designated colors so that similar color range of designated color do not overlap each other.

(18) The image processing system according to item (13), (14), (15), (16) or (17), wherein aforesaid color adjusting unit checks if an output hue data vale for the input hue data value is of monotonous increase or monotonous decrease including no-change corresponding to an input hue data value, and corrects aforesaid output hue data value if it is neither monotonous increase nor monotonous decrease.

(19) The image processing apparatus according to the Item (13), (14), (15), (16), (17) or (18), wherein a section to obtain image data is provided and the color adjusting unit conducts color adjustment for the hue data value of aforesaid image data obtained.

(20) The image processing apparatus according to any one of items (13), (14), (15), (16), (17), (18) and (19), wherein a first conversion unit which convert RGB data into Lch data is provided, and aforesaid hue data value is h data value obtained by the first converting section.

(21) The image processing system according to item (20), comprising a second conversion unit, which converts Lch data including h data after color adjustment into RGB data.

(22) The image processing system according to item (21), comprising a third conversion unit which converts RGB data obtained by the second conversion unit into CMYK data, and an image forming unit which forms an image based on aforesaid CMYK data.

(23) The image processing system provided with a color adjusting unit that moves a hue of similar color range of a designated color close to a hue of aforesaid designated color.

(24) The image processing system provided with a color adjusting unit that moves a hue of similar color range of a designated color away from a hue of aforesaid designated color is provided.

(25) The image forming system comprising a color adjusting unit which increases a hue data value of a first area in the similar color range of a designated color and decreases a hue data value of a second area in the similar color range of a designated color to conduct color adjustment.

(26) The image forming system according to item (25), wherein aforesaid color adjusting unit maintains a hue data value of aforesaid designated color.

(27) The image forming system according to item (25) or (26), comprising an operation section which determines stepwise an amount of color adjustment to be conducted by aforesaid color adjusting unit.

(28) The image forming system according to item (25), (26) or (27), comprising an operating section to designate one or more colors mentioned above.

(29) The image forming system according to item (25), (26), (27) or (28), wherein the number of designated colors is two or more, and aforesaid color adjusting unit determines similar color ranges of different designated colors, so that similar color ranges of designated colors do not overlap each other.

(30) The image forming system according to item (25), (26), (27), (28) or (29) wherein aforesaid color adjusting unit checks if an output hue data value for the input hue data value is of monotonous increase or monotonous decrease including no-change corresponding to an input hue data value and corrects aforesaid output hue data value if it is neither monotonous increase nor monotonous decrease.

(31) The image forming system according to any one of the items (25), (26), (27), (28), (29) and (30), wherein a section to obtain image data is provided and aforesaid color adjusting unit executes color adjusting for a hue data value of aforesaid image data obtained.

(32) The image forming apparatus according to any one of items (25), (26), (27), (28), (29), (30) and (31), wherein a first conversion unit which converts RGB data into Lch data is provided, and aforesaid hue data value is h data value obtained by the first-conversion section.

(33) The image forming system according to item (32), comprising a second conversion unit which converts Lch data including h data after color adjustment into RGB data.

(34) The image forming system according to item (33), comprising a third conversion unit converts RGB data obtained by the second conversion section into CMYK data and an image forming unit which forms an image based on aforesaid CMYK data.

(35) The image forming system provided with a color adjusting unit that moves a hue of similar color range of a designated color close to a hue of aforesaid designated color.

(36) The image processing system provided with a color adjusting unit that moves a hue of similar color range of a designated color away from a hue of aforesaid designated color.

(37) A program for making a computer realize color adjusting function to conduct color adjustment by increasing a hue data value in a first area of the similar color range of a designated color and by decreasing a hue data value in a second the area of the similar color range.

(38) The program according to item (37), wherein a hue data value of aforesaid designated color is maintained, when realizing aforesaid color adjusting function.

(39) The program according to item (37) or (38), wherein the program further make the computer realize a function to designate an amount of adjustment of color adjustment in aforesaid color adjusting function by operations through an operating section.

(40) The program according to any one of items (37), (38) and (39), further making the computer realize a function to designate one or more designated colors by operations through the operating section.

(41) The program according to any one of items (37), (38), (39) and (40), wherein when the computer realizes aforesaid color adjusting function, a similar color range of each designated color is established so that similar color ranges for different designated colors do not overlap each other, when the number of the designated colors is two or more.

(42) The program according to any one of items (37), (38), (39), (40) and (41) wherein when the computer realizes the color adjusting function, the color adjusting function checks if an output hue data value for the input hue data value is of monotonous increase or monotonous decrease including no-change corresponding to an input hue data value, and corrects aforesaid output hue data value if it is neither monotonous increase nor monotonous decrease.

(43) The program according to any one of items (37), (38), (39), (40), (41) and (42), further making the computer realize an acquisition function to acquire an image data, wherein when the computer realizes the acquisition function for acquiring image data and the color adjusting function, color adjustment is executed for a hue data value of the image data acquired.

(44) The program according to any one of items (37), (38), (39), (40), (41), (42), and (43), further making the computer realize a first conversion function that converts RGB data into Lch data, and the hue data value is h data value which is obtained by the first conversion function.

(45) The program according to item (44), further making the computer realizes a second conversion function that converts Lch data including h data after color adjustment into RGB data.

(46) The program according to item (45), further making the computer realize a third conversion function which converts RGB data obtained by the second conversion function into CMYK data and an image forming function which forms an image based on said CMYK data.

(47) The program for making a computer realize a color adjusting function that moves a hue value in the similar color area of a designated color close to a hue value of the designated color.

(48) The program for making a computer realize a color adjusting function that moves a hue value in the similar color range of a designated color to be away from a hue value of the designated color.

According to the items (1), (13), (25) and (37), various expressions of colors included in the color area near a designated color can be realized, because a hue data value within a first area of the similar color range of a designated color is increased and a hue data value within a second area of the similar color range of a designated color is decreased.

According to the items (2), (14), (26) and (38), various expressions of colors included in the similar color range near the designated color can be realized without changing colors for the designated color, because the hue data value of a designated color is maintained.

According to the items (3), (15), (27) and (39), an adjusting amount of color adjustment can be designated stepwise with instructions of users.

According to the items (4), (16), (28) and (40), one or more colors can be designated with instructions of users.

According to the items (5), (17), (29) and (41), it is possible to prevent that the color adjustment of other designated color is affected by the color adjustment of each designated color, because the similar color range of each designated color is established so that similar color ranges of different designated colors do not overlap each other, when the number of different designated colors is two or more.

According to the items (6), (18), (39) and (42), inversion of hue is prevented because an output hue data value is corrected so that an output hue data value for an input hue data value may be monotonous increases including no-change or monotonous decrease.

According to the items (7), (19), (31) and (43), an image data are obtained and color adjustment can be conducted for a hue data value of the image data obtained.

According to the items (8), (20), (32) and (44), h data obtained by converting RGB data into Lch data can be used as a hue data value.

According to the items (9), (21), (33) and (45), Lch data including h data after color adjustment can be converted into RGB data.

According to the items (10), (22), (34) and (46), RGB data can be converted into CMYK data, and an image can be formed based on the CMYK data.

According to the items (11), (23), (35) and (47), various expressions of the colors included in the similar color range of the designated color can be realized, by moving a hue data value within the similar color range of a designated color close to the hue data vale of designated color.

According to the items (12), (24), (36) and (48), the expression of the colors included in similar color range of the designated color can be diversified, by moving a hue value within the similar color range of a designated color away from the hue value of designated color.

What is claimed is:

1. An image processing apparatus, comprising:
a member which designate a color; and
a color adjusting unit which adjusts a color by increasing a first hue data value of a first area in a similar color range to a designated color and decreasing a second hue data value of a second area in the similar color range.

2. The image processing apparatus of claim 1, wherein the color adjusting unit does not adjust a hue data value of the designated color.

3. The image processing apparatus of claim 1, further comprising an operation panel which provides keys to specify adjusting amount in the color adjusting unit.

4. The image processing apparatus of claim 1, wherein the member designates at least two colors.

5. The image processing apparatus of claim 4, wherein the color adjusting unit establishes a similar color range of each designated color so that the similar color range does not overlap with another similar color range of different designated color.

6. The image processing apparatus of claim 1, further comprising a printer unit which prints out an image depending on the color adjustment.

7. The image processing apparatus of claim 1, wherein the color adjusting unit checks if adjusted hue data values are in monotonous increase or in monotonous decrease, and corrects the adjusted hue data values when the adjusted hue data values are not in monotonous increase or in monotonous decrease.

8. An image processing apparatus comprising:
a member which designate a color; and
a color adjusting unit which adjusts so that a color in a similar color range of a designated color comes close to a the designated color.

9. The image processing apparatus of claim 8, wherein the color adjusting unit does not adjust the designated color, and adjusts a similar color to the designated color.

10. The image processing apparatus of claim 8, further comprising an operation panel which provides keys to specify adjusting amount in the color adjusting unit.

11. The image processing apparatus of claim 8, wherein the member designates at least two colors.

12. The image processing apparatus of claim 11, wherein the color adjusting unit establishes a similar color range of each designated color so that the similar color range does not overlap with another similar color range of different designated color.

13. The image processing apparatus of claim 8, further comprising a printer unit which prints out an image depending on the color adjustment.

14. An image processing apparatus, comprising:
an operation panel which provides keys to designate a color, and to select a level of color adjusting close to the designated color or a level of color adjusting away from the designated color.

15. The image processing apparatus of claim 14, further comprising a color adjusting unit which adjusts a selected color with the selected level of color adjusting.

16. The image processing apparatus of claim 15, wherein the color adjusting unit does not adjust the designated color, and adjusts only a similar color to the designated color.

17. The image processing apparatus of claim 8, further comprising an operation panel which provides keys to designate at least two colors.

18. The image processing apparatus of claim 8, further comprising a printer unit which prints out an image depending on the color adjustment.
